(19) United States
(12) Patent Application Publication
(10) Pub. No.: US 2003/0096444 A1
(43) Pub. Date: May 22, 2003

(54) Heterobipolar transistor with T-shaped emitter terminal contact and method of manufacturing it

(76) Inventor: Stefan Kraus, Baierbrunn (DE)

Correspondence Address: LERNER AND GREENBERG, P.A., Post Office Box 2480, Hollywood, FL, 33022-2480, US

(21) Appl. No.: 10/253,450

(22) Filed: Sep. 24, 2002

Related U.S. Application Data
(63) Continuation of application No. PCT/EP01/02512, filed on Mar. 6, 2001.

(30) Foreign Application Priority Data
Mar. 24, 2000 (EP) 00106474.0

(51) Int. Cl. H01L 21/00

(52) U.S. Cl. 438/60

(57) ABSTRACT

During production, an emitter opening is formed in an insulating layer deposited on successive layers of the transistor. The emitter contact is configured in the opening, covering the edge of the opening in a defined manner. A mesa structure is subsequently etched using the emitter contact as an etching mask. The remaining electrically insulating area acts as an aperture for electric current that is limited to a central region of the emitter layer and an emitter contact layer.

### CROSS-REFERENCE TO RELATED APPLICATION

This application is a continuation of copending International Application No. PCT/EP01/02512, filed Mar. 6, 2001, which designated the United States and was not published in English.

### BACKGROUND OF THE INVENTION

### Field of the Invention

The method relates to a heterobipolar transistor having epitaxially grown semiconductor layers, and to a method for manufacturing the heterobipolar transistor.

The invention lies within the technical field of methods for manufacturing semiconductor components that are composed of a number of epitaxially grown semiconductor layers. In heterobipolar transistors, components based on the InGaP/GaAs material system, which have a number of advantages over those components based on the AlGaAs/GaAs material system, have been known for some time. Referring to FIG. 1 herein, there is shown a prior art InGaP/GaAs heterobipolar transistor composed of, for example, a semi-insulating GaAs substrate 1, an n⁺-type doped GaAs subcollector layer 2, an n⁻-doped GaAs collector layer 3, a p⁺-doped GaAs base layer 4, an n-doped InGaP emitter layer 5, and an n⁺-doped InGaAs cover layer 6. Such a component is described, for example, in the publication by M. Hafizi in “IEEE Transactions on Electron Devices”, Vol. 45, No. 9, September 1998, pages 1862-1868. The mesa-shaped structure composed of the emitter layer 5 and the cover layer 6 is obtained using projection-lithographic resist patterning and a plurality of etching steps.

However, the main disadvantage of this component structure is that the emitter-collector current I_{c} (see arrows) flows from the emitter terminal contact 9 through the cover layer 6, in some cases close to the side walls of the cover layer 6, to the collector layer 3 and the subcollector layer 2. However, these side walls have been affected to a greater or lesser extent by the etching process and the underetching that occurs in the process, resulting in a large number of defects in the side wall and in its direct vicinity. These crystal defects increasingly lead to surface recombinations that adversely effect the efficiency of the component.

### SUMMARY OF THE INVENTION

It is accordingly an object of the invention to provide a heterobipolar transistor and a method for manufacturing a heterobipolar transistor which overcomes the above-mentioned disadvantages of the prior art apparatus and methods of this general type.

A mesa-shaped structure that contains the emitter terminal contact is formed, and adverse effects on the function of the component due to the influence of the side walls of the emitter layer and/or of an emitter contact layer that may possibly be present are avoided.

With the foregoing and other objects in view there is provided, in accordance with the invention, a method for manufacturing a heterobipolar transistor. The method includes steps of:

a) growing a sequence of epitaxial layers including a collector layer, a base layer and an emitter layer on a semiconductor substrate;

b) growing an insulation layer and forming an emitter opening in the insulation layer, the opening extending to emitter layer;

c) depositing an emitter terminal contact in the emitter opening such that the emitter terminal contact extends at least along a circumferential section of the emitter opening and on the surface of the insulation layer beyond an edge of the opening;

d) generating a mesa-shaped structure by removing the insulation layer and at least partially removing the emitter layer outside the emitter terminal contact by performing at least one etching step using the emitter terminal contact as an etching mask;

e) depositing at least one base terminal contact on a section outside the mesa-shaped structure;

f) removing the base layer at least in a section outside the mesa-shaped structure, and if there is a remaining portion of the emitter layer in the section outside the mesa-shaped structure, removing the remaining portion of the emitter layer at least in the section outside the mesa-shaped structure; and

g) depositing at least one collector terminal contact on the section outside the mesa-shaped structure.

In accordance with an added mode of the invention, the method includes: after growing the emitter layer in step a), growing an emitter contact layer, and then growing the insulation layer on the emitter contact layer in step b).

In accordance with an additional mode of the invention, the insulation layer grown in step b) is an SiN layer.

In accordance with another mode of the invention, the emitter terminal contact includes a first contact layer and a second contact layer.

In accordance with a further mode of the invention, the first contact layer includes a WSi layer or a W/WSi layer sequence.

In accordance with a further added mode of the invention, the second contact layer includes a Ti/Pt/Au layer sequence.

In accordance with a further additional mode of the invention, the method includes: in step c), first depositing the first contact layer entirely over the surface, then after depositing the first contact layer, using an image reversal photographic technique to deposit the second contact layer in the emitter opening and beyond the edge, and then using the second contact layer as a mask while removing the first contact layer outside the second contact layer.

In accordance with yet an added mode of the invention, the method includes: performing the steps of removing the first contact layer in step c) and removing the insulation layer in step d) in direct succession in a single etching step.

In accordance with yet an additional mode of the invention, the method includes: after growing the emitter layer in step a), growing an emitter contact layer, and then growing the insulation layer on the emitter contact layer in step b); and after removing the insulation layer, removing the emitter contact layer.

In accordance with yet another mode of the invention, the method includes: in step d), removing the emitter layer by sputtering.

In accordance with yet a further mode of the invention, the method includes: in step d), removing the emitter layer by sputtering with Ar.

With the foregoing and other objects in view there is provided, in accordance with the invention, a heterobipolar transistor, including: a sequence of epitaxial layers including a collector layer, a base layer, an emitter layer, and an emitter terminal contact; a mesa-shaped structure having a circumferential section, the mesa-shaped structure including the emitter terminal contact; and an electrically insulating zone running at least along the circumferential section of the mesa-shaped structure. The electrically insulating zone is formed between the emitter terminal contact and the emitter layer.

In accordance with an added feature of the invention, the emitter terminal contact has a section that faces the emitter layer and that is surrounded by the electrically insulating zone.

In accordance with an additional feature of the invention, the electrically insulating zone includes SiN.

In accordance with another feature of the invention, the electrically insulating zone is formed from SiN.

In accordance with a further feature of the invention, an emitter contact layer is configured between the emitter terminal contact and the emitter layer.

The electrically insulating zone that is formed from the insulating layer during the manufacturing process forms an aperture between the emitter terminal contact and the emitter layer or possibly an additional emitter contact layer or cover layer so that the electrical current is restricted to a central region of the emitter layer and/or of the emitter contact layer and is kept away from the side walls of these layers. The emitter terminal contact can be formed in such a way that it has a T-shaped structure with an upper part lying on the side of the electrically insulating zone facing away from the emitter layer, and having a lower part coming to rest within the electrically insulating zone that runs in an annular shape.

The emitter is usually an elongated region, for example, a region with an area of 3×30 μm², as in the exemplary embodiment described below. In this case, it is sufficient if during manufacture, the edge covering is performed along the longitudinal sides of the emitter opening during the deposition of the emitter terminal contact so that the insulation zone is also formed only on the longitudinal sides.

The insulation layer in method step b) may be, for example, a SiN layer.

The emitter terminal contact can be composed of a single contact layer or can be formed by two contact layers in a manner known per se. Here, it is possible to form a first contact layer, preferably composed of a WSi layer or a W/WSi layer sequence, and a second contact layer, preferably composed of a Ti/Pt/Au layer sequence. Here, in method step c), first the first contact layer can be deposited over the entire surface and the second contact layer can then preferably be deposited in the emitter opening and the edge region by using the image reversal photographic technique, and then the first contact layer can be removed outside the second contact layer while using the second contact layer as a mask. The removal of the first contact layer in method step c) and the removal of the insulation layer in method step d) can then be carried out in direct succession in a single etching step. After removing the insulation layer, if appropriate, first the emitter contact layer is removed in method step d), and then the emitter layer is removed in the method step d).

In method step e), it is possible, in a manner known per se, to deposit two base terminal contacts symmetrically on each side of the mesa-shaped structure.

In method step f), a second mesa-shaped structure is preferably formed while using the first mesa-shaped structure and the base terminal contacts (protected with SiN) as etching masks. Here, the etching step is carried out as far as the collector layer or the subcollector layer below it.

However, as an alternative, in method step f), it is also possible to carry out contact hole etching as far as the collector layer or the subcollector layer.

In any case, in method step g), at least one collector terminal contact is then deposited on a section that is no longer covered by the base layer.

Other features which are considered as characteristic for the invention are set forth in the appended claims.

Although the invention is illustrated and described herein as embodied in a heterobipolar transistor with T-shaped emitter terminal contact and method of manufacturing it, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a cross-sectional view of a prior art heterobipolar transistor;

FIGS. 2A-N illustrate the individual manufacturing steps of an exemplary embodiment of a method for manufacturing a heterobipolar transistor.

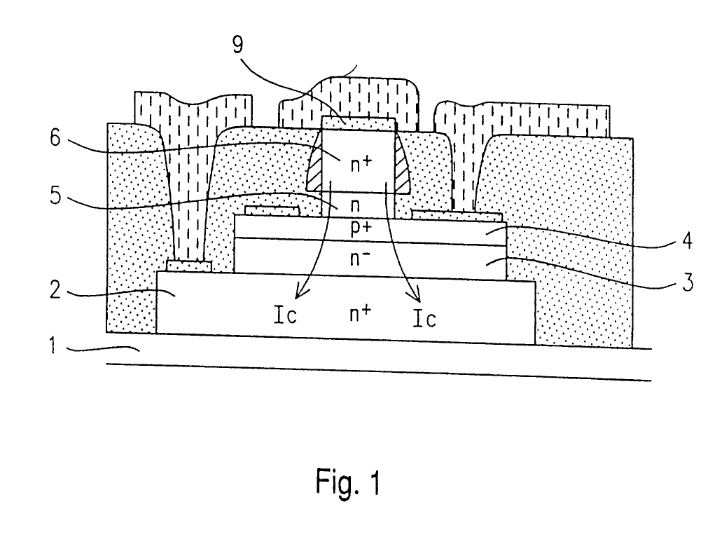

### DESCRIPTION OF THE PREFERRED EMBODIMENTS

In the exemplary embodiment, an InGaP/GaAs heterobipolar transistor is manufactured. For the sake of clarity of the individual drawings, usually only part of the substrate is illustrated in order to clarify the process steps carried out on the surface.

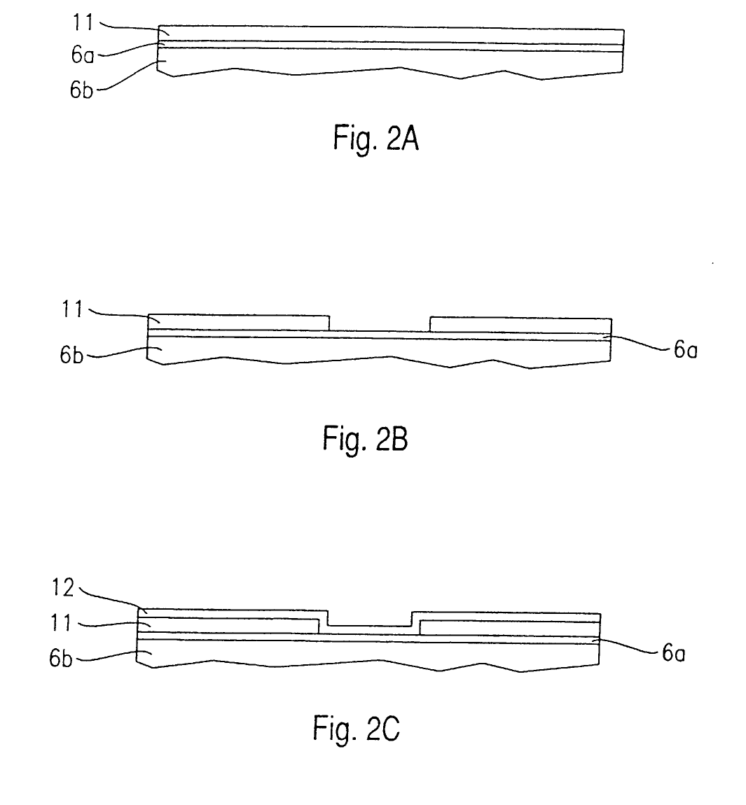

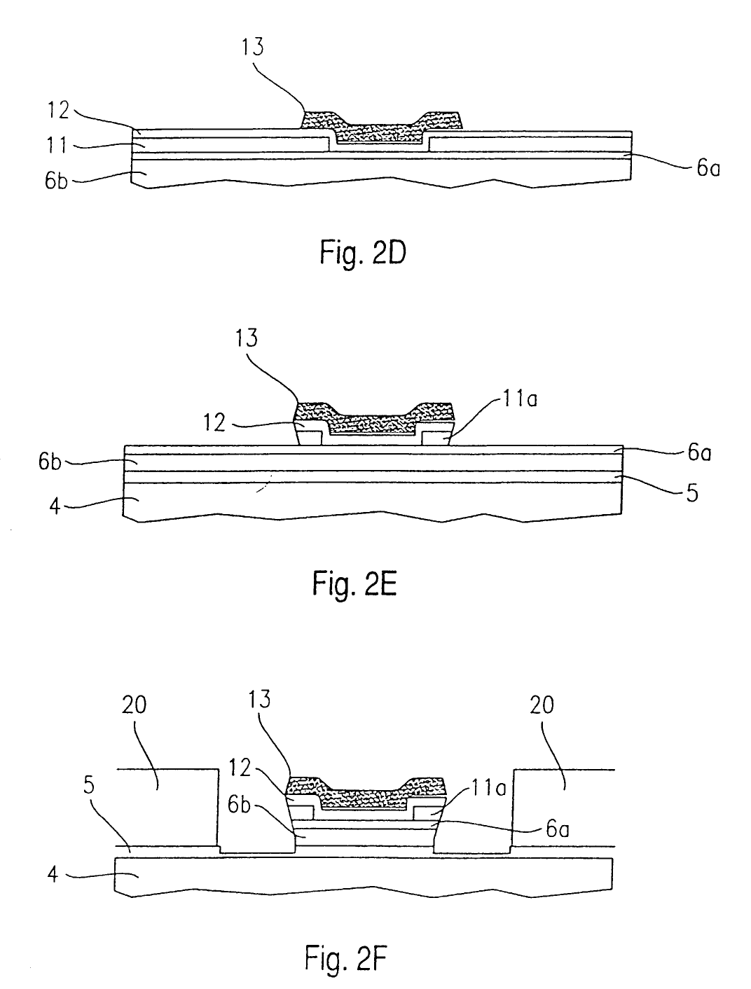

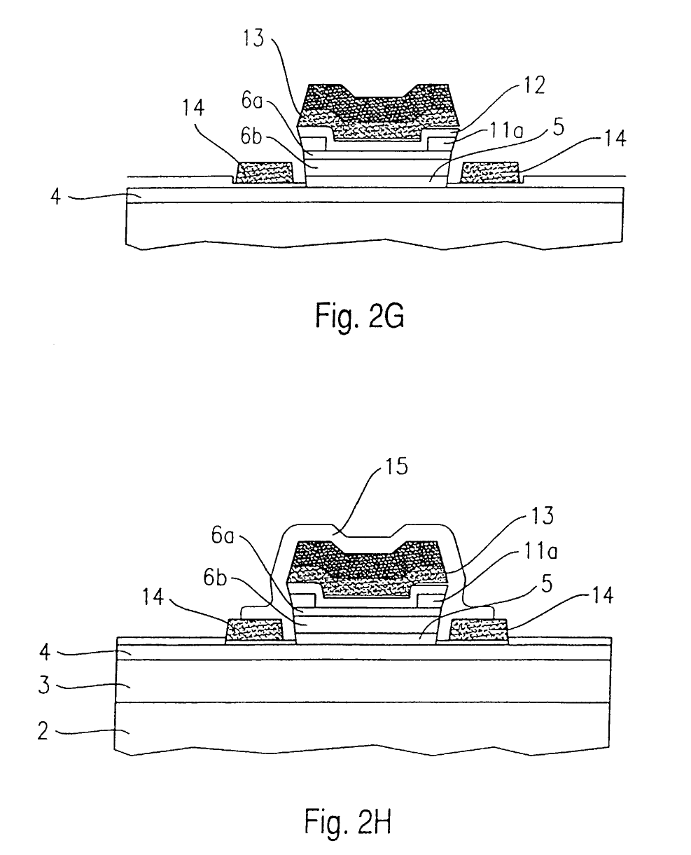

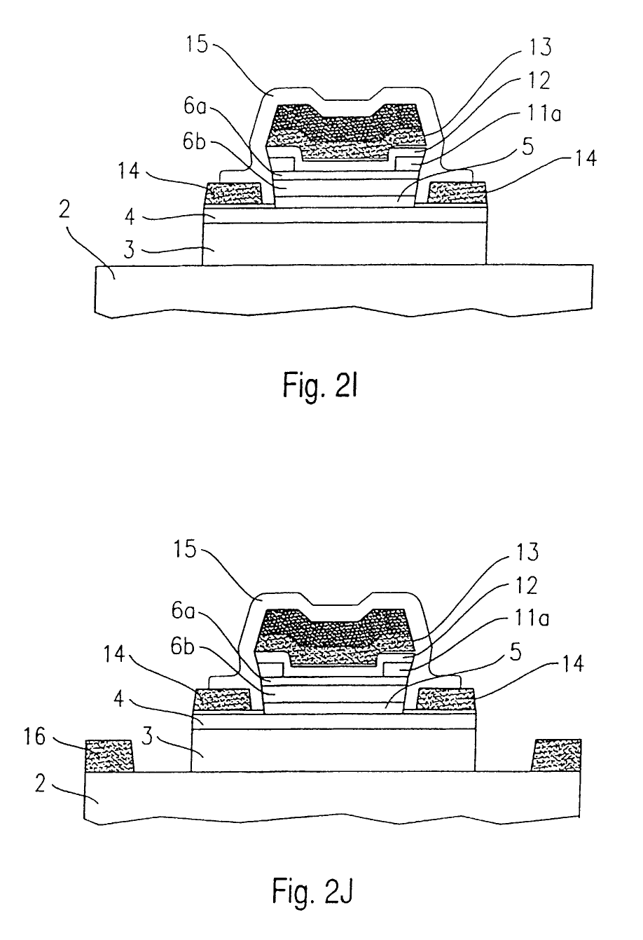

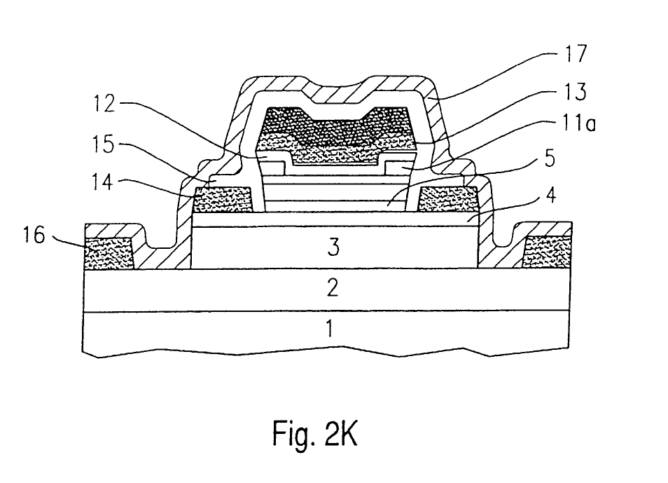

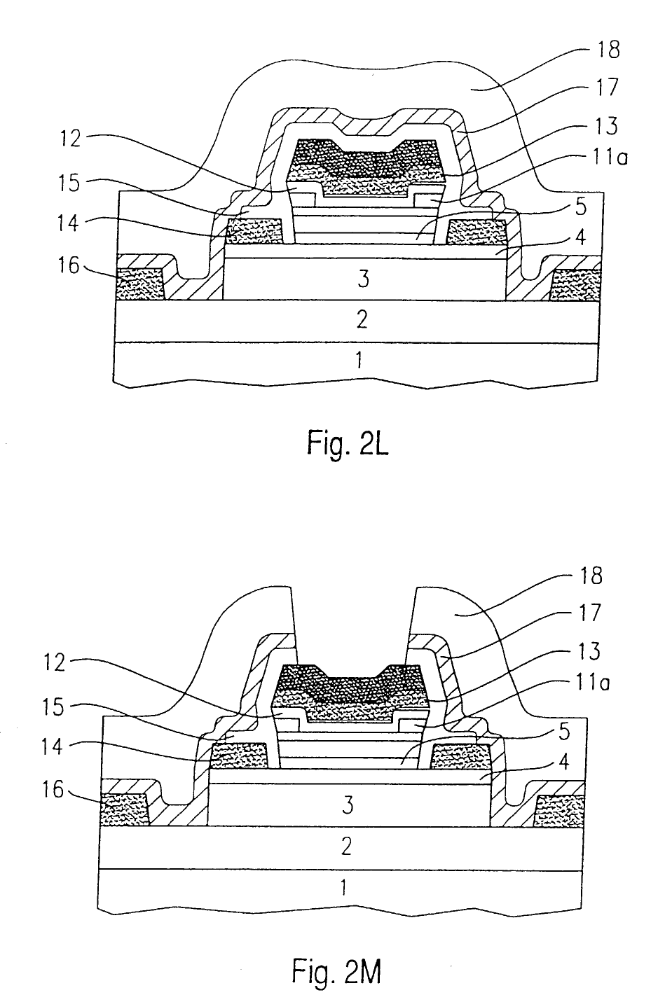

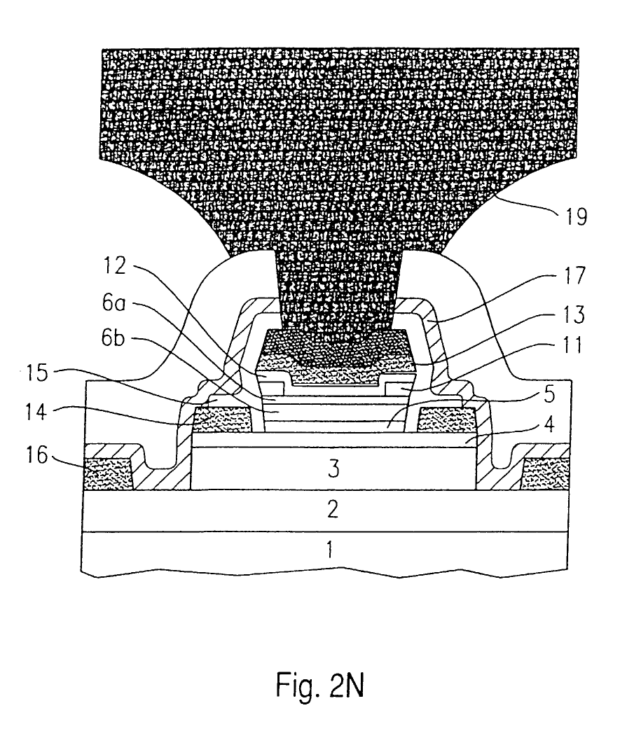

Referring now to the figures of the drawing in detail and first, particularly, to FIG. 2N thereof, the entire fabricated component is illustrated. FIG. 2N shows a cross-sectional view of a semiconductor heterobipolar transistor. This cross-sectional view is taken through the mesa-shaped structures that form the transistor.

On the basis of the illustration in FIG. 2N, first an n⁺-type GaAs subcollector layer 2 is grown on a semi-insulating GaAs substrate 1. Then, a weakly n-type doped GaAs collector layer 3 is grown thereon. A p⁺-doped GaAs base layer 4 is then deposited on the n-doped GaAs collector layer 3, and an n-doped InGaP emitter layer 5 is applied to the p⁺-type doped GaAs base layer 4. Finally, an emitter cover layer or contact layer, which may be, for example, a double layer composed of an upper n⁺-doped InGaAs cover layer 6a and a lower n⁻-doped GaAs cover layer 6b, is deposited on the emitter layer 5. The individual layers may be grown, for example, using MBE (molecular beam epitaxy), MOCVD (metal organic chemical vapor deposition), or a combined method.

According to FIG. 2A, first an insulation layer 11, for example, an SiN layer, is applied to the upper cover layer 6a. The thickness of this insulation layer is, for example, 300 nm.

Using photolithography, resist patterning and subsequent dry-chemical etching, an emitter opening is then formed in the insulation layer 11 as shown in FIG. 2B. The size of the emitter is defined by this emitter opening. The size of the emitter opening is correspondingly typically 3×30 μm². The insulation layer 11 is completely removed in the emitter opening so that the surface of the upper cover layer 6a is exposed at the bottom of the emitter opening.

After cleaning up the surface, a first electrical contact layer 12 is then deposited in a sputter process as shown in FIG. 2C. This contact layer 12 is deposited in the present case as a layer sequence W/WSi with an overall thickness of 80 nm. The sputter process results in approximately uniform coverage of the surface with the first contact layer 12.

Then, as shown in FIG. 2D, a second electrical contact layer 13 is applied in the emitter opening that is covered by the first electrical contact layer 12. The second electrical contact layer 13 is applied using the image reversal photographic technique, and overlaps both longitudinal sides of the emitter opening by approximately 0.5 μm. A layer sequence Ti/Pt/Au is deposited in a manner known per se as a second electrical contact layer 13.

As shown in FIG. 2E, the first electrical contact layer 12 (W/WSi) and the insulation layer 11 (SiN) can then be patterned dry-chemically in a single process in a self-aligning fashion using the second electrical contact layer 13 as a mask, and the InGaAs semiconductor surface of the upper cover layer 6a as an etch stop. By optimizing the process parameters (isotropic/unisotropic etching, overetching), the underetching of the emitter metalization can be influenced selectively. As a result of this etching step, an electrically insulating zone 11a remains. The emitter terminal contact that is formed from the contact layers 12 and 13 is formed as a T-shaped structure on the zone 11a.

Then, as shown in FIG. 2F, the InGaAs and GaAs cover layers 6a and 6b of the heterobipolar transistor are first removed by etching using self-aligning patterning. To do this, it is possible, for example, to use an inductive coupled plasma system (ICP). It provides the advantage that it is possible to choose precisely between unisotropic (high bias) etching and isotropic (low bias) etching by setting the high frequency power at the bottom electrode. In a two-stage process, the In-containing layers (InGaAs) are first etched with high power (high physical content), and the In-free layers (GaAs) are then etched immediately with a low power. By detecting the emitted plasma light, it is possible to determine the endpoint of the InGaAs etching and the GaAs etching, and the etching steps can be stopped in a reproducible fashion. The InGaP emitter layer 5 serves here initially as an etch stop layer which has a very low etching rate at the selected etching parameter. By suitably selecting the power and the overetching time, the underetching of the GaAs layer can be influenced selectively.

Then, as shown in FIG. 2F, using a patterned photoresist layer 20, a section of the emitter layer 5 is partially removed over a location where the base terminal contacts 14 (see FIG. 2G) will be formed. Given a normal doping, a residual thickness of 30-50 nm no longer produces a conductive connection so that an electrical connection is not produced between the base terminal contacts and the emitter. The removal can be carried out, for example, by an Ar sputter step, after which the self-aligning vapor deposition of the base terminal contacts 14 is then carried out in the method step shown in FIG. 2G. In this case, the layer sequence Pt/Ti/Pt/Au is selected for the base terminal contacts 14. Platinum is necessary as the first metalization layer in order to form flat contact with the base layer 4 via the remaining InGaP layer. Alternatively, the emitter layer can also be removed completely by the sputter step, or can have already been completely removed by the preceding etching.

What is referred to as the base fork, that is to say the distance between the base terminal contacts 14, which is formed in the method step shown in FIG. 2G, has a total width of 2 μm. The distance between the emitter and the base metalization is determined by the height of the base metalization, the height of the SiN passivation, and the underetching of the emitter.

During the deposition of the base terminal contacts 14, such an additional metalization layer is likewise deposited on the emitter terminal contact 13.

Then, as shown in FIG. 2H, the passivation over the entire surface of the structure is carried out with a passivation layer 15, which may be composed of, for example, SiN and may have a thickness of 300 nm. Using a photoresist mask or a spacer technique, it is then possible to remove the SiN again such that those semiconductor surfaces that are necessary for the following base etching are opened. The region between the emitter and the base metal must however be protected with SiN from the processes that then follow.

After removing the resist mask using NMP (N-methylpyrrolidone), it is then possible to carry out the base etching directly as shown in FIG. 2I. Here, it is in principle possible to adopt precisely the same procedure as for the emitter etching. The residual layer of the InGaP emitter layer 5 that is still present is first removed with high power. In the second step, the GaAs material of the collector layer 3 is etched with a relatively low power. The etching can be stopped very homogenously on the wafer by using an AlGaAs etch stop layer that is present between the collector layer 3 and the subcollector layer 2.

Before the collector metalization, the 20-nm-thin AlGaAs etch stop layer is first removed in an Ar sputter step. Then, collector terminal contacts 16, preferably made of the layer sequence Ge/Au/Ni/Au, are applied on both sides of the mesa-shaped structure. The application of an alloy for the base and collector terminal contacts can then take place in one process step.

Before the application of the collector terminal contacts 16, a second mesa-shaped structure is consequently formed in the exemplary embodiment shown in FIG. 2I by patterning the base layer 4 and the collector layer 3. However, this is not absolutely necessary within the sense of the invention. It is alternatively also possible to carry out one or more contact hole etchings through the base layer 4 to the collector layer 3 or through the base layer 4 and the collector layer 3 as far as the subcollector layer 2 in order subsequently to fill the contact holes with electrically conductive material, and thus to form the collector metalization.

Then, as shown in FIG. 2K, an etching mask layer 17 made of SiN is applied for the purpose of insulating the components from one another. The etching mask layer 17 is patterned in such a way that it is flush with the outer edge of the collector terminal contacts 16. During the insulation etching, electrical insulation from component to component is then implemented by first etching into the subcollector layer 2 as far as an AlGaAs buffer layer that is arranged between the substrate 1 and the subcollector layer 2, and then in a second step, the buffer layer is removed and an etching of approximately 300 nm into the substrate 1 is then performed.

Then, as shown in FIG. 2L a planarization layer 18 composed of SiN is then applied to the insulated component structure. This planarization layer 18 is preferably grown in three process steps in three layers with thicknesses of 300, 200 and 300 nm respectively.

So that the emitters of a plurality of transistors can then be connected to what is referred to as an airbridge in a manner known per se, as shown in FIG. 2M, the emitter metalization is opened by performing a dry-chemical etching step using a photoresist mask. As shown in FIG. 2N, an airbridge metalization 19 is then introduced into the emitter metalization by performing a galvanic process in order to connect the emitters of the transistors to one another using a standard airbridge technique.

I claim:

1. A method for manufacturing a heterobipolar transistor, which comprises:
a) growing a sequence of epitaxial layers including a collector layer, a base layer and an emitter layer on a semiconductor substrate;
b) growing an insulation layer and forming an emitter opening in the insulation layer, the opening extending to emitter layer;
c) depositing an emitter terminal contact in the emitter opening such that the emitter terminal contact extends at least along a circumferential section of the emitter opening and on the surface of the insulation layer beyond an edge of the opening;
d) generating a mesa-shaped structure by removing the insulation layer and at least partially removing the emitter layer outside the emitter terminal contact by performing at least one etching step using the emitter terminal contact as an etching mask;
e) depositing at least one base terminal contact on a section outside the mesa-shaped structure;
f) removing the base layer at least in a section outside the mesa-shaped structure, and if there is a remaining portion of the emitter layer in the section outside the mesa-shaped structure, removing the remaining portion of the emitter layer at least in the section outside the mesa-shaped structure; and
g) depositing at least one collector terminal contact on the section outside the mesa-shaped structure.

2. The method according to claim 1, which comprises: after growing the emitter layer in step a), growing an emitter contact layer, and then growing the insulation layer on the emitter contact layer in step b).

3. The method according to claim 1, wherein: the insulation layer grown in step b) is an SiN layer.

4. The method according to claim 1, wherein: the emitter terminal contact includes a first contact layer and a second contact layer.

5. The method according to claim 4, wherein: the first contact layer includes a component selected from a group consisting of a WSi layer and a W/WSi layer sequence.

6. The method according to claim 4, wherein: the second contact layer includes a Ti/Pt/Au layer sequence.

7. The method according to claim 4, which comprises:
in step c), first depositing the first contact layer entirely over the surface, then after depositing the first contact layer, using an image reversal photographic technique to deposit the second contact layer in the emitter opening and beyond the edge, and then using the second contact layer as a mask while removing the first contact layer outside the second contact layer.

8. The method according to claim 7, which comprises:
performing the steps of removing the first contact layer in step c) and removing the insulation layer in step d) in direct succession in a single etching step.

9. The method according to claim 1, which comprises:
after growing the emitter layer in step a), growing an emitter contact layer, and then growing the insulation layer on the emitter contact layer in step b); and
after removing the insulation layer, removing the emitter contact layer.

10. The method according to claim 1, which comprises: in step d), removing the emitter layer by sputtering.

11. The method according to claim 1, which comprises: in step d), removing the emitter layer by sputtering with Ar.

12. A heterobipolar transistor, comprising:
a sequence of epitaxial layers including a collector layer, a base layer, an emitter layer, and an emitter terminal contact;
a mesa-shaped structure having a circumferential section, said mesa-shaped structure including said emitter terminal contact; and
an electrically insulating zone running at least along said circumferential section of said mesa-shaped structure;
said electrically insulating zone being formed between said emitter terminal contact and said emitter layer.

13. The heterobipolar transistor according to claim 12, wherein: said emitter terminal contact has a section that faces said emitter layer and that is surrounded by said electrically insulating zone.

14. The heterobipolar transistor according to claim 12, wherein: said electrically insulating zone includes SiN.

15. The heterobipolar transistor according to claim 12, wherein: said electrically insulating zone is formed from SiN.

16. The heterobipolar transistor according to claim 12, comprising: an emitter contact layer configured between said emitter terminal contact and said emitter layer.
